(19) United States
(12) Patent Application Publication
(10) Pub. No.: US 2009/0075024 A1
(43) Pub. Date: Mar. 19, 2009

(54) METHOD FOR PRODUCING A THERMAL BARRIER COATING AND THERMAL BARRIER COATING FOR A COMPONENT PART

(75) Inventor: Thomas Cosack, Windach (DE)

Correspondence Address: CROWELL & MORING LLP;INTELLECTUAL PROPERTY GROUP, P.O. BOX 14300, WASHINGTON, DC, 20044-4300, US

(73) Assignee: MTU Aero Engines GmbH, Munich (DE)

(21) Appl. No.: 12/281,739

(22) PCT Filed: Mar. 2, 2007
(86) PCT No.: PCT/DE2007/000390

§ 371 Date: Sep. 4, 2008

(30) Foreign Application Priority Data
Mar. 9, 2006 (DE) 10 2006 010 860.4

(51) Int. Cl. B32B 7/00; C23C 16/455; C23C 16/06; C23C 14/34; C23C 14/46

(52) U.S. Cl. 428/119; 427/248.1; 427/255.23; 204/192.1; 204/192.11; 204/192.15

(57) ABSTRACT

A method for producing a ceramic thermal barrier coating on a component part for use in compressor and turbine components by a vapor depositing process, and a ceramic thermal barrier coating, is disclosed. The method includes: a) provision of a ceramic vapor for depositing on the component part; b) depositing of the ceramic vapor on the component part to form a thermal barrier coating having a columnar structure, the columns being oriented substantially perpendicular to a surface of the component part; and c) varying of at least one method parameter during method step b) such that the resultant thermal barrier coating has columns of alternating decreasing and increasing diameters. The ceramic thermal barrier coating has a columnar structure and the columns are oriented substantially perpendicular to a surface of the corresponding part. The columns have alternately decreasing and increasing diameters.

This application claims the priority of International Application No. PCT/DE2007/000390, filed Mar. 2, 2007, and German Patent Document No. 10 2006 010 860.4, filed Mar. 9, 2006, the disclosures of which are expressly incorporated by reference herein.

### BACKGROUND AND SUMMARY OF THE INVENTION

The present invention relates to a method for producing a ceramic thermal barrier coating on a component part for use in compressor and turbine components by means of a vapor depositing method as well as a thermal barrier coating for component parts for use in compressor and turbine components, wherein the thermal barrier coating is normally comprised of a ceramic thermal barrier coating having a columnar structure and columns being oriented substantially perpendicular to a surface of the component part. The invention also relates to a component part for use in compressor and turbine components comprised of a metal substrate and a thermal barrier coating applied at least partially to the metal substrate.

Various methods for producing a ceramic thermal barrier coating on component parts are known from the prior art, in particular for use in compressor and turbine components. In this case, a ceramic layer is applied to the component part using either a plasma spray method or by means of a physical vapor depositing method (PVD). Ceramic layers with columnar structures arise through the use of physical vapor depositing methods, in particular also electron beam vaporization (EB-PVD). The columns in this case have a constant thickness over their lengths. Even the columnar substructure of the column is homogeneous. The advantage of ceramic thermal barrier coatings produced in this manner over the thermal barrier coatings produced by a thermal spray process is that they have an improved resistance to thermal change due to the columnar structure. In addition, the individual columns permit an expansion and contraction of the column structure without stress occurring which, in extreme cases, could lead to individual parts of the thermal barrier coating flaking off. Because of the additional application of thermal insulating ceramic layers on the cited component parts, the material temperature of the component part is reduced and strength is thereby maintained. Zirconium oxide with various stabilizers, particularly yttrium oxide, is used as the ceramic material most of the time in this case. Methods for producing ceramic thermal barrier coatings and corresponding thermal barrier coatings for metal component parts for use in compressor and turbine components are known from German Patent Document Nos. DE 601 03 526 T2 and DE 693 18 856 T2 as well as from U.S. Pat. Nos. 4,321,311 A, 4,401,697 A, 4,405,659 A and 5,514,482.

However, what is disadvantageous in terms of the known methods for producing ceramic thermal barrier coatings as well as the thermal barrier coatings fabricated from them is that relatively thick columnar structures are generated with the use of physical vapor depositing methods. However, the relatively high density disadvantageously promotes the flow of heat within the ceramic thermal barrier coating.

As a result, the objective of the present invention is providing a generic thermal barrier coating for a component part with a very clearly reduced thermal conductivity.

It is further the objective of the invention to provide a generic method for producing a ceramic thermal barrier coating, in which the resulting thermal barrier coating features a distinct—in particular reduced-thermal conductivity.

Furthermore, another objective of the present invention is providing a component part for use in compressor and turbine components comprised of a metal substrate and a thermal barrier coating applied at least partially to the metal substrate, wherein the thermal barrier coating features a very clearly reduced thermal conductivity as compared with known thermal barrier coatings.

An inventive method for producing a ceramic thermal barrier coating on a component part for use in compressor and turbine components comprises a vapor depositing method with the following method steps: a) provision of a ceramic vapor for depositing on the component part; b) depositing of the ceramic vapor on the component part to form a thermal barrier coating having a columnar structure, the columns being oriented substantially perpendicular to a surface of the component part; and c) varying of at least one method parameter during method step b), in such a way that the resultant thermal barrier coating comprises columns of alternating decreasing and increasing diameters. The vapor depositing method is particularly a physical vapor depositing method, such as, e.g., an electron beam vapor depositing method. However, using a cathode sputtering method or an arc welding vaporization method as well as CVD methods is also conceivable. The use of a vapor depositing method guarantees that the developing thermal barrier coating has a columnar structure, and therefore has the already known advantages of such structured ceramic thermal barrier coatings. According to the invention, the emerging columns have alternating decreasing and increasing diameters. Because of the alternating decreasing and increasing diameters, pores develop between the individual columns in the course of the layer development of the thermal barrier coating; these pores contribute to clearly reducing the heat flow, and thus the thermal conductivity of the emerging thermal barrier coating. The feature of the decreasing and increasing diameters should also be understood in particular in this case such that adjacent columns do not touch at least in sections over their lengths and do not run parallel. The same applies to any substructure that may develop. In addition, the smaller diameters of the columns advantageously massively inhibit the flow of heat so that this also results in a substantial reduction in the thermal conductivity of the emerging thermal barrier coating.

In other advantageous embodiments of the inventive method, the method is carried out in a coating chamber, in particular a vacuum chamber. In this case, the to-be-coated component part is introduced into the coating chamber and the ceramic thermal barrier coating is deposited on it. The component part is normally warmed or heated at least on the to-be-coated surface of the component part.

In addition, it is possible for oxygen and inert gas to be fed in during method step b) and the varying of at least one method parameter during method step c) is comprised of varying the partial pressure of oxygen and/or of the inert gas during coating or in the coating chamber. In the process, the partial pressures and even the overall pressure can be regulated via the gas flows or the pumping capacity.

However, it is also possible for the to-be-coated component part to be moved during method step b) and the varying of at least one method parameter during method step c) to be comprised of varying the type of component movement and/or component speed during coating. In this case, the component part can be rotated in particular so that the varying of at least one method parameter during method step c) is comprised of varying the rotational speed during coating. In addition, it is possible for the varying of at least one method parameter during method step c) to be comprised of varying the deposition rate of the ceramic vapor on the component part during coating. Finally, it is possible to vary at least one method parameter during method step c) by varying the pressure during coating in the coating chamber. The cited measures result in the inventive layer structure of the ceramic thermal barrier coating, wherein the emerging columns have alternating decreasing and increasing diameters along their longitudinal extensions.

In a further advantageous embodiment of the inventive method, the ceramic vapor or the ceramic material used is comprised of zirconium oxide, yttrium oxide or a mixture thereof. Other ceramic materials are also conceivable. Normally, the thermal barrier coating is deposited in a thickness of between 1 and 400 μm; however, other layer thickness are also conceivable.

In a further advantageous embodiment of the inventive method, a bonding layer is formed at least partially between the to-be-coated component part surface and the thermal barrier coating. The bonding layer in this case can be comprised of MCrAlY alitized/Al-enriched surfaces, or Pt/Al. In this case, the bonding layer can be applied by means of known thermal spray methods, galvanic methods, diffusion treatment methods or even by means of physical vapor depositing methods. In addition, in another embodiment of the inventive method it is possible for an intermediate layer of aluminum oxide to be formed at least partially between the to-be-coated component part surface and the bonding layer.

An inventive thermal barrier coating is comprised of ceramic material and has a columnar structure or grain structure, wherein the columns are oriented substantially perpendicular to a surface of the component part. According to the invention, the columns have alternating decreasing and increasing diameters along their longitudinal extensions. The grain boundaries of the individual columns can touch at least partially, advantageously forming pore spaces between the individual columns. The inventive structure or formation of the individual columns results in a clear reduction in the thermal conductivity of the thermal barrier coating since the small diameters of the individual columns massively inhibit the flow of heat. In addition, the pores formed within the thermal barrier coating significantly reduce the flow of heat.

In an advantageous embodiment of the thermal barrier coating, the ceramic material of the thermal barrier coating is comprised of zirconium oxide, yttrium oxide or a mixture thereof. The use of other suitable ceramic materials to form the thermal barrier coating is also conceivable, however. The thermal barrier coating normally features a thickness of between 1 and 400 μn, wherein other thicknesses are also conceivable.

An inventive component part for use in compressor and turbine components is comprised of a metal substrate and an inventive thermal barrier coating applied at least partially to the metal substrate, as described in the foregoing. A correspondingly coated component part has a clearly lower wear rate with a correspondingly higher service life due to the clear reduction of the thermal conductivity of the thermal barrier coating in accordance with the present invention.

In another advantageous embodiment of the inventive component part, a bonding layer, in particular made of MCrAlY and Pt/Al, can be formed at least partially between the substrate and the thermal barrier coating. It is also possible for an intermediate layer made of aluminum oxide to be formed at least partially between the substrate and the bonding layer. The inventive component part is an element of a gas turbine engine in particular.

Additional advantages, characteristics and details are disclosed in the following description of an exemplary embodiment that is depicted graphically.

### BRIEF DESCRIPTION OF THE DRAWINGS

The drawings show:

FIG. 1 is a schematic sectional representation of a component with a thermal barrier coating in accordance with the prior art; and

FIG. 2 is a schematic sectional representation of a component with an inventive thermal barrier coating.

### DETAILED DESCRIPTION OF THE DRAWINGS

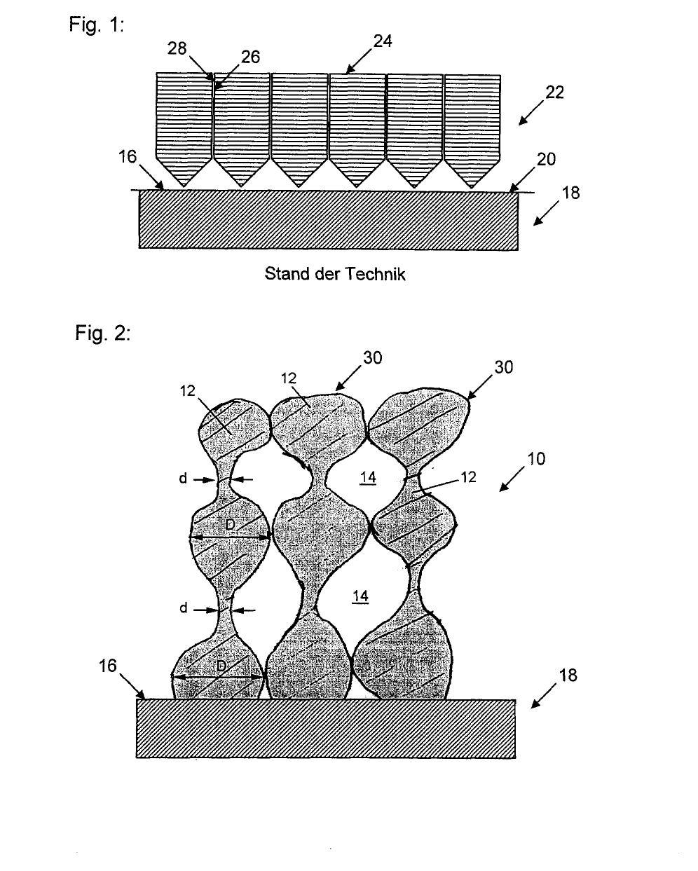

FIG. 1 shows a schematic sectional representation of a component part or a metallic substrate 18 with a thermal barrier coating 22 arranged on it. A bonding layer 20, in particular made of MCrAlY or Pt/Al, is formed between the thermal barrier coating 22 and the surface 16 of the component part. One can see that the thermal barrier coating 22 has a columnar structure, wherein the individual columns 24 are oriented substantially perpendicular to the surface 16 of the component part. The grain boundaries 26, 28 of respectively different columns 24 touch in the process over the longitudinal extension of the column 24. This results in a relatively thick columnar structure that promotes the flow of heat within the ceramic thermal barrier coating 22.

FIG. 2 shows a schematic sectional representation of a ceramic thermal barrier coating 10, which was applied to a component part surface 16 of the component part 18 or was deposited there. One can see that the thermal barrier coating 10 is again comprised of columns 12, which are oriented substantially perpendicular to the surface 16 of the component part. In contrast to the known column structure depicted in FIG. 1, the columns 12 shown in FIG. 2 have alternating decreasing and increasing diameters d, D along their longitudinal extensions. One can see that the grain boundaries 30 of the individual columns touch at least partially, but pore spaces 14 are formed between the individual columns 12. Because of the small diameters d in the individual columns, the heat flow within the thermal barrier coating 10 is massively inhibited. In addition, the density of the thermal barrier coating 10 is clearly reduced due to the pores 14 so that the flow of heat within the thermal barrier coating 10 is also hereby clearly reduced.

1-24. (canceled)

25. A method for producing a ceramic thermal barrier coating on a component part for use in compressor and turbine components comprising a vapor depositing process having the following steps:
a) provision of a ceramic vapor for depositing on the component part;
b) depositing of the ceramic vapor on the component part to form a thermal barrier coating having a columnar structure, wherein columns are oriented substantially perpendicular to a surface of the component part; and
c) varying of at least one method parameter during method step b) in such a way that the columns of the thermal barrier coating have alternating decreasing and increasing diameters.

26. The method according to claim 25, wherein the vapor depositing process is a physical vapor depositing method.

27. The method according to claim 26, wherein the physical vapor depositing method is an electron beam vapor depositing method, a cathode sputtering method, or an arc welding vaporization method.

28. The method according to claim 25, wherein the method is carried out in a coating chamber and wherein the coating chamber is a vacuum chamber.

29. The method according to claim 25, wherein oxygen and inert gas are fed in during method step b) and wherein the varying of the at least one method parameter during method step c) includes varying a partial pressure of the oxygen and/or of the inert gas during coating or in a coating chamber.

30. The method according to claim 25, wherein the component part is moved during method step b) and wherein the varying of the at least one method parameter during method step c) includes varying a type of component movement and/or a component speed during coating.

31. The method according to claim 30, wherein the component part rotates and the varying of the at least one method parameter during method step c) includes varying a rotational speed during coating.

32. The method according to claim 25, wherein the varying of the at least one method parameter during method step c) includes varying a deposition rate of the ceramic vapor on the component part during coating.

33. The method according to claim 25, wherein the varying of the at least one method parameter during method step c) includes varying a pressure during coating or in a coating chamber.

34. The method according to claim 25, wherein the ceramic thermal barrier coating is comprised of zirconium oxide, yttrium oxide or a mixture thereof.

35. The method according to claim 25, wherein the ceramic thermal barrier coating is deposited in a thickness of between 1 and 500 μm.

36. The method according to claim 25, wherein a bonding layer is formed at least partially between the surface of the component part and the ceramic thermal barrier coating.

37. The method according to claim 36, wherein the bonding layer includes MCrAlY and/or Pt/Al or is comprised thereof and/or is Al-enriched or alitized.

38. The method according to claim 36, wherein an intermediate layer of aluminum oxide is formed at least partially between the surface of the component part and the bonding layer.

39. A thermal barrier coating for a component part for use in compressor and turbine components, wherein the thermal barrier coating is comprised of a ceramic thermal barrier coating having a columnar structure, wherein columns are oriented substantially perpendicular to a surface of the component part, and wherein the columns have alternating decreasing and increasing diameters.

40. The thermal barrier coating according to claim 39, wherein a grain boundary of adjacent columns touch at least partially.

41. The thermal barrier coating according to claim 39, wherein pore spaces are formed between adjacent columns.

42. The thermal barrier coating according to claim 39, wherein the ceramic thermal barrier coating is comprised of zirconium oxide, yttrium oxide or a mixture thereof.

43. The thermal barrier coating according to claim 39, wherein the thermal barrier coating has a thickness of between 1 and 500 μm.

44. A component part of a compressor or a turbine, comprising a metal substrate and a thermal barrier coating, wherein the thermal barrier coating is comprised of a ceramic thermal barrier coating having a columnar structure, wherein columns are oriented substantially perpendicular to a surface of the component part, and wherein the columns have alternating decreasing and increasing diameters.

45. The component part according to claim 44, wherein a bonding layer is formed at least partially between the metal substrate and the thermal barrier coating.

46. The component part according to claim 45, wherein the bonding layer is comprised of MCrAlY and/or is Al-enriched or alitized.

47. The component part according to claim 45, wherein an intermediate layer of aluminum oxide is formed at least partially between the metal substrate and the bonding layer.

48. The component part according to claim 44, wherein the component part is an element of a gas turbine engine.
